(19) United States
(12) Patent Application Publication
(10) Pub. No.: US 2023/0117098 A1
(43) Pub. Date: Apr. 20, 2023

(54) DISPLAY SUBSTRATE, COLOR FILTER SUBSTRATE, DISPLAY PANEL AND DISPLAY DEVICE

(71) Applicants: Yunnan Invensight Optoelectronics Technology Co., Ltd., Kunming, Yunnan (CN); BOE Technology Group Co., Ltd., Beijing (CN)

(72) Inventors: Chenyu CHEN, Beijing (CN); Pengcheng LU, Beijing (CN); Zhijian ZHU, Beijing (CN); Xiaochuan CHEN, Beijing (CN)

(21) Appl. No.: 17/914,664

(22) PCT Filed: Oct. 25, 2021
(86) PCT No.: PCT/CN2021/126214

§ 371 Date: Sep. 26, 2022

(30) Foreign Application Priority Data
Mar. 11, 2021 (CN) 202110265207.1

(51) Int. Cl. H10K 59/35; H10K 59/126

(52) U.S. Cl. CPC H10K 59/351; H10K 59/126

(57) ABSTRACT

A display substrate, a color filter substrate, a display panel and a display device are disclosed in the present application, relating to the field of display technologies. In the display substrate, because the area of the orthographic projection of the first opening region on the first base substrate is less, the area of the orthographic projection of the second opening region on the first base substrate is larger, and the area of the orthographic projection of the third opening region on the first base substrate is larger, the first subpixel of the display substrate emits less light, and the second subpixel and the third subpixel emit more light. In addition, because the wavelength of the first color is larger and the proportion of the light of the first color in the light emitted from the display substrate is less, the color cast of the display panel can be avoided and the display panel has a better display effect.

### CROSS-REFERENCE TO RELATED APPLICATION

This application is a U.S. national phase application based on PCT/CN2021/126214, field on Oct. 25, 2021, which claims priority to the Chinese Patent Application No. 202110265207.1, filed on Mar. 11, 2021, and entitled “DISPLAY SUBSTRATE, COLOR FILTER SUBSTRATE, DISPLAY PANEL AND DISPLAY DEVICE.” the entire contents of which are incorporated herein by reference in their entireties.

### TECHNICAL FIELD

The present disclosure relates to the field of display technologies, and in particular, relates to a display substrate, a color filter substrate, a display panel and a display device.

### BACKGROUND

The display substrate includes a plurality of subpixels, and the plurality of subpixels emits light of different colors to make the display substrate display a color image.

### SUMMARY OF THE UTILITY MODEL

Embodiments of the present disclosure provide a display substrate, a color filter substrate, a display panel, and a display device. The technical solutions are as follows.

According to some embodiments of the present disclosure, a display substrate is provided.

The display substrate includes:

a first base substrate; and

a plurality of first subpixels, a plurality of second subpixels, and a plurality of third subpixels disposed on the first base substrate, a wavelength of light of a first color emitted by the first subpixels is greater than a wavelength of light of a second color emitted by the second subpixels and greater than a wavelength of light of a third color emitted by the third subpixels

wherein an area of an orthographic projection of a first opening region of the first subpixel on the first base substrate is less than an area of an orthographic projection of a second opening region of the second subpixel on the first base substrate and less than an area of an orthographic projection of a third opening region of the third subpixel on the first base substrate.

Optionally, the first color is red, the second color is blue, and the third color is green.

Optionally, the area of the orthographic projection of the second opening region on the first base substrate is equal to the area of the orthographic projection of the third opening region on the first base substrate; and

a shape of the orthographic projection of the second opening region on the first base substrate is identical to a shape of the orthographic projection of the third opening region on the first base substrate.

Optionally, the plurality of second subpixels and the plurality of third subpixels are arrayed, a first spacing region is disposed between opening regions of two adjacent subpixels in a target direction, and the orthographic projection of the first opening region on the first base substrate is within an orthographic projection of the first spacing region on the first base substrate;

wherein a color of light emitted by the two adjacent subpixels includes at least one of the second color and the third color.

Optionally, the shape of the orthographic projection of the second opening region on the first base substrate and the shape of the orthographic projection of the third opening region on the first base substrate are hexagons, and a shape of the orthographic projection of the first opening region on the first base substrate is a rhombus.

Optionally, a side length of the hexagon is greater than or equal to a side length of the rhombus.

Optionally, the area of the orthographic projection of the second opening region on the first base substrate is less than or equal to three times the area of the orthographic projection of the first opening region on the first base substrate.

Optionally, a shape of the orthographic projection of the first opening region on the first base substrate, the shape of the orthographic projection of the second opening region on the first base substrate and the shape of the orthographic projection of the third opening region on the first base substrate are hexagons.

Optionally, a second spacing region is disposed between the first opening region and at least one of opening regions adjacent to the first opening region; and

the display substrate further includes a black matrix, wherein the black matrix is disposed within the second spacing region.

Optionally, boundary lines of any two adjacent opening regions of a plurality of first opening regions, a plurality of second opening regions and a plurality of third opening regions are overlapped with each other.

Optionally, the display substrate further includes: a plurality of fourth subpixels disposed on the first base substrate, wherein the fourth subpixels emit light of a fourth color;

wherein an area of an orthographic projection of a fourth opening region of the fourth subpixel is less than the area of the orthographic projection of the second opening region on the first base substrate and less than the area of the orthographic projection of the third opening region on the first base substrate.

Optionally, the fourth color is white.

Optionally, each of the subpixels of the display substrate includes two stacked light-emitting units.

According to some embodiments of the present disclosure, a color filter substrate is provided. The color filter substrate includes:

a second base substrate; and

a plurality of first color blocks with a first color, a plurality of second color blocks with a second color and a plurality of third color blocks with a third color disposed on the second base substrate, wherein a wavelength of light of the first color is greater than a wavelength of light of the second color and greater than a wavelength of light of the third color; wherein

an area of an orthographic projection of the first color block on the second base substrate is less than an area of an orthographic projection of the second color block on the second base substrate and less than an area of an orthographic projection of the third color block on the second base substrate; and

at least one of the second color blocks and/or at least one of the third color blocks is disposed between two adjacent first color blocks in a target direction.

According to some embodiments of the present disclosure, a display panel is provided. The display panel includes the display substrate as described in the above aspect, or an array substrate and the color filter substrate as described in the above aspect.

According to some embodiments of the present disclosure, a display device is provided. The display device includes a power supply assembly and the display panel as described in the above aspect;

wherein the power supply assembly is configured to supply power to the display panel.

### BRIEF DESCRIPTION OF THE DRAWINGS

In order to describe the technical solutions in the embodiments of the present disclosure more clearly, the following briefly describes the accompanying drawings required for describing the embodiments. Apparently, the accompanying drawings in the following description show merely some embodiments of the present disclosure, and those of ordinary skill in the art can still derive other drawings from these accompanying drawings without creative efforts.

FIG. 1 is a schematic diagram of a structure of a display substrate according to some embodiments of the present disclosure:

FIG. 2 is a top view of the display substrate shown in FIG. 1;

FIG. 3 is a schematic diagram of the relationship between the viewing angle and the brightness of each color of light without using the display substrate according to some embodiments of the present disclosure;

FIG. 4 is a schematic diagram of second subpixels and third subpixels according to some embodiments of the present disclosure:

FIG. 5 is a schematic diagram of a structure of another display substrate according to some embodiments of the present disclosure;

FIG. 6 is a schematic diagram of a structure of still another display substrate according to some embodiments of the present disclosure;

FIG. 7 is a schematic diagram of first subpixels, second subpixels and third subpixels according to some embodiments of the present disclosure;

FIG. 8 is a schematic diagram of a structure of still another display substrate according to some embodiments of the present disclosure:

FIG. 9 is a schematic diagram of a structure of still another display substrate according to some embodiments of the present disclosure;

FIG. 10 is a schematic diagram of a structure of still another display substrate according to some embodiments of the present disclosure;

FIG. 11 is a schematic diagram of a structure of still another display substrate according to some embodiments of the present disclosure;

FIG. 12 is a schematic diagram of a structure of still another display substrate according to some embodiments of the present disclosure;

FIG. 13 is a schematic diagram of a structure of still another display substrate according to some embodiments of the present disclosure;

FIG. 14 is a schematic diagram of a structure of still another display substrate according to some embodiments of the present disclosure;

FIG. 15 is a schematic diagram of a structure of still another display substrate according to some embodiments of the present disclosure:

FIG. 16 is a schematic diagram of a structure of still another display substrate according to some embodiments of the present disclosure;

FIG. 17 is a schematic diagram of the relationship between the viewing angle and the brightness of the light of each color using the display substrate according to some embodiments of the present disclosure;

FIG. 18 is a schematic diagram of a structure of still another display substrate according to some embodiments of the present disclosure:

FIG. 19 is a schematic diagram of a structure of subpixels according to some embodiments of the present disclosure;

FIG. 20 is a schematic diagram of a structure of a color filter substrate according to some embodiments of the present disclosure;

FIG. 21 is a top view of the color filter substrate shown in FIG. 20;

FIG. 22 is a schematic diagram of a light emitted by a display substrate according to some embodiments of the present disclosure:

FIG. 23 is a schematic diagram of a light emitted by another a display substrate according to some embodiments of the present disclosure:

FIG. 24 is a schematic diagram of a structure of another color filter substrate according to some embodiments of the present disclosure;

FIG. 25 is a schematic diagram of a structure of a display panel according to some embodiments of the present disclosure:

FIG. 26 is a schematic diagram of a structure of another display panel according to some embodiments of the present disclosure:

FIG. 27 is a schematic diagram of a structure of still another display panel according to some embodiments of the present disclosure; and

FIG. 28 is a schematic diagram of a structure of a display device according to some embodiments of the present disclosure.

### DETAILED DESCRIPTION

To make the objectives, technical solutions, and advantages of the present disclosure clearer, the following further describes implementations of the present disclosure in detail with reference to the accompanying drawings.

However, when the user's viewing angle is large, the display panel has color cast and the display panel has poorer display effect.

FIG. 1 is a schematic diagram of a structure of a display substrate according to some embodiments of the present disclosure. As shown in FIG. 1, the display substrate 10 includes a first base substrate 101, a plurality of first subpixels 102, a plurality of second subpixels 103, and a plurality of third subpixels 104 disposed on the first base substrate 101.

A color of light emitted by the first subpixel is a first color, a color of light emitted by the second subpixel is a second color, and a color of light emitted by the third subpixel is a third color. A wavelength of the light of the first color is greater than a wavelength of the light of the second color and greater than a wavelength of the light of the third color.

FIG. 2 is a top view of the display substrate shown in FIG. 1. Referring to FIG. 2, it can be seen that an area of an orthographic projection of a first opening region 102a of the first subpixel 102 on the first base substrate 101 is less than an area of an orthographic projection of the second opening region 103a of the second subpixel 103 on the first base substrate 101. The area of the orthographic projection of the first opening region 102a of the first subpixel 102 on the first base substrate 101 is less than an area of an orthographic projection of the third opening region 104a of the third subpixel 104 on the color first base substrate 101. That is, the area of the orthographic projection of the first opening region 102a of the first subpixel 102 on the first base substrate 101 is less, while the area of the orthographic projection of the second opening region 103a of the second subpixel 103 on the first base substrate 101 and the area of the orthographic projection of the third opening region 104a of the third subpixel 104 on the first base substrate 101 is larger. The opening region of the subpixel is the region where the light emitted from the subpixel can be emitted from the display substrate 10.

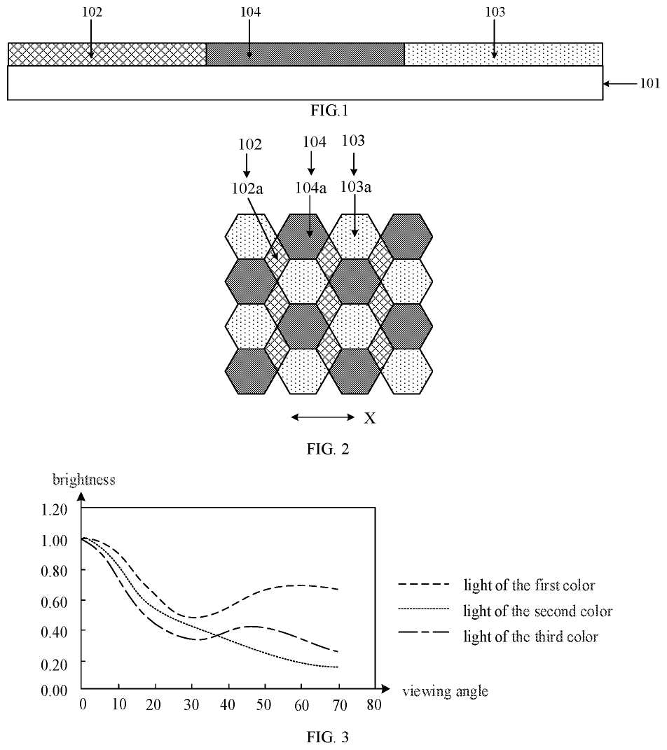

In the embodiments of the present disclosure, referring to FIG. 3, in the case that the user's viewing angle is large, the difference between the intensity of the light of a larger wavelength (light of the first color) and the intensity of the light of a smaller wavelength (light of the second color) is large, and this results in the color viewed by the user tending to the color corresponding to the light of the larger wavelength. In other words, the display panel has a color cast when the user's viewing angle is large. For these reasons, the possibility of color cast in the display panel can be reduced by reducing the intensity of the light of a larger wavelength when the user's viewing angle is large.

Because the wavelength of the light of the first color is larger, the light of the first color causes a color cast in the display panel. In the embodiments of the present disclosure, designing the area of the orthographic projection of the first opening region 102a of the first subpixel 102 of the first color on the first base substrate 101 to be less can reduce the proportion of the light of the first color in the light emitted from the display substrate, thus reducing the intensity of the light of the first color and avoiding color cast in the display substrate.

In summary, the embodiments of the present disclosure provide a display substrate. In the display substrate, because the area of the orthographic projection of the first opening region on the first base substrate is less, the area of the orthographic projection of the second opening region on the first base substrate is larger, and the area of the orthographic projection of the third opening region on the first base substrate is larger, the first subpixel of the display substrate emits less light, and the second subpixel and the third subpixel emit more light. In addition, because the wavelength of the first color is larger and the proportion of the light of the first color in the light emitted from the display substrate is smaller, the color cast of the display panel can be avoided and the display panel has a better display effect.

Optionally, the first color is red, the second color is blue, and the third color is green.

In the embodiments of the present disclosure, the area of the orthographic projection of the second opening region 103a of the second subpixel 103 on the first base substrate 101 is equal to the area of the orthographic projection of the third opening region 104a of the third subpixel 104 on the first base substrate 101. The shape of the orthographic projection of the second opening region 103a of the second subpixel 103 on the first base substrate 101 is identical to the shape of the orthographic projection of the third opening region 104a of the third subpixel 104 on the first base substrate 101.

The area of the orthographic projection of the second opening region 103a of the second subpixel 103 on the first base substrate 101 is different from the area of the orthographic projection of the third opening region 104a of the third subpixel 104 on the first base substrate 101. The shape of the orthographic projection of the second opening region 103a of the second subpixel 103 on the first base substrate 101 is different from the shape of the orthographic projection of the third opening region 104a of the third subpixel 104 on the first base substrate 101. The embodiments of the present disclosure do not limit the area relationship and shape relationship between the orthographic projection of the second opening region 103a of the second sub-pixel 103 and the orthographic projection of the third opening region 104a of the third sub-pixel 104 on the first base substrate 101.

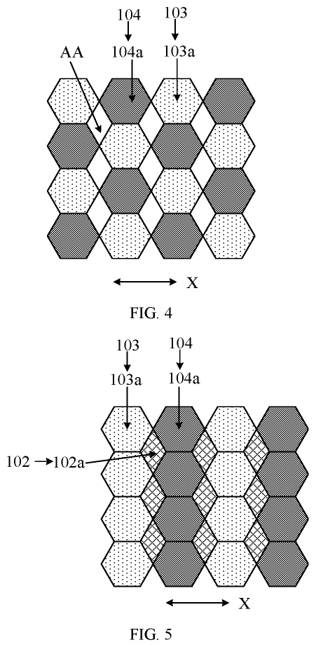

FIG. 4 is a schematic diagram of a plurality of second subpixels and a plurality of third subpixels according to some embodiments of the present disclosure. Referring to FIG. 4, a plurality of second subpixels 103 and a plurality of third subpixels 104 are arrayed and a first spacing region AA is disposed between the opening regions of two adjacent subpixels in a target direction X. The orthographic projection of the first opening region 102a of the first subpixel 102 is within the orthographic projection of the first spacing region AA on the first base substrate 101. The color of light emitted by the two adjacent subpixels includes at least one of the second color and the third color.

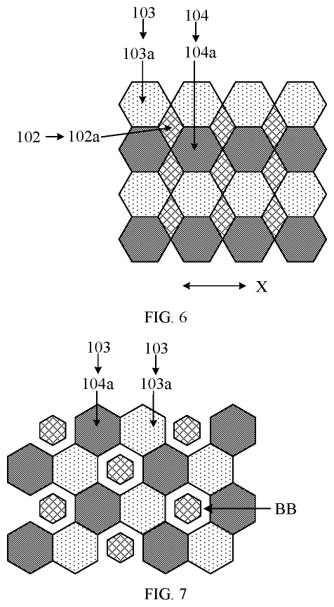

In the embodiments of the present disclosure, referring to FIG. 2 and FIG. 4, the second subpixel 103 and the third subpixel 104 are staggeredly arranged in the target direction X and in a direction perpendicular to the target direction X. Alternatively, referring to FIG. 5, the second sub-pixel 103 and the third sub-pixel 104 are only staggeredly arranged in the target direction X. Alternatively, referring to FIG. 6, the second sub-pixel 103 and the third sub-pixel 104 are only staggeredly arranged in the direction perpendicular to the target direction X.

Optionally, assuming that the target direction X is the row direction of the pixels, the direction perpendicular to the target direction X is the column direction of the pixels. In FIG. 5, a plurality of subpixels in one column include subpixels with only one color. For example, the first column subpixels are all the second subpixels 103 with the second color, and the second column subpixels are all the third subpixels 104 with the third color. In FIG. 6, a plurality of subpixels in one row include subpixels with only one color. For example, the first row of subpixels are all the second subpixels 103 with the second color, and the second row of subpixels are all the third subpixels 104 with the third color.

In the embodiments of the present disclosure, referring to FIG. 1 and FIGS. 4 to 6, the shape of the orthographic projection of the second opening region 103a of the second subpixel 103 on the first base substrate 101 and the shape of the orthographic projection of the third opening region 104a of the third subpixel 104 on the first base substrate 101 are both hexagons, and the shape of the first opening region 102a of the first subpixel 102 on the first base substrate 101 is a rhombus. The side length of the hexagon is greater than or equal to the side length of the rhombus.

In FIG. 4, boundary lines of any two adjacent opening regions of the plurality of second opening regions 103a and the plurality of third opening regions 104a are overlapped with each other. In this way, four of the plurality of second opening regions 103a and the plurality of third opening regions 104a enclose the first spacing region AA, which is a rhombus. The area of the orthographic projection of the first opening region 102a on the first base substrate 101 is equal to the area of the orthographic projection of the first spacing region AA on the first base substrate 101. That is, the first opening region 102a is overlapped with the boundary line of the adjacent second opening region 103a or the adjacent third opening region 104a. In this case, the side length of the hexagon is equal to the side length of the rhombus.

That is, in FIG. 1 and FIGS. 4 to 6, the boundary lines of any two adjacent opening regions is overlapped with each other in the plurality of first opening regions 102a, the plurality of second opening regions 103a, and the plurality of third opening regions 104a. Thus, it is possible to have no spacing region between any two adjacent opening regions, and it is possible to not provide a black matrix in the display substrate 10.

In the case that the side length of the hexagon and the side length of the rhombus are both a, it should be noted that the area S1 of the hexagon satisfies:

$$S 1 = \frac{3 \times \sqrt{3}}{2} \times {a}^{2} ,$$

and the area S2 of the rhombus satisfies:

$$S 1 = \frac{\sqrt{3}}{2} \times {a}^{2} .$$

Based on the area S1 of the hexagon and the area S2 of the rhombus above, it is clear that the area of the hexagon is three times the area of the rhombus.

In this way, in FIG. 1 and in FIGS. 4 to 6, the area of the orthographic projection of the second opening region 103a on the first base substrate 101 and the area of the orthographic projection of the third opening region 104a on the first base substrate 101 are both three times the area of the orthographic projection of the first opening region 102a on the first base substrate 101.

Of course, in the case that the boundary lines of two adjacent opening regions are not overlapped with each other among the plurality of first opening regions 102a, the plurality of second opening regions 103a, and the plurality of third opening regions 104a, a black matrix is provided in the spacing region between these two adjacent color blocks, thereby avoiding light from being emitted from the spacing region between these two adjacent opening regions.

For example, the boundary lines of any two adjacent opening regions are overlapped with each other among a plurality of second opening regions 103a and a plurality of third opening regions 104a. In the case that the area of the orthographic projection of the first opening region 102a on the first base substrate 101 is less than the area of the orthographic projection of this first spacing region AA on the first base substrate 101, a spacing region is disposed between the first opening region 102a and at least one of opening regions adjacent to the first opening region 102a. In this case, the side length of the hexagon is greater than the side length of the rhombus. The at least one opening region adjacent to the first opening region 102a includes at least one second opening region 103a and/or at least one third opening region 104a.

In the embodiments of the present disclosure, the shape of the orthographic projection of the first opening region 102a on the first base substrate 101, the shape of the orthographic projection of the second opening region 103a on the first base substrate 101 and the shape of the orthographic projection of the third opening region 104a on the first base substrate 101 are other shapes.

Referring to FIG. 7, the shape of the orthographic projection of the first opening region 102a on the first base substrate 101, the shape of the orthographic projection of the second opening region 103a on the first base substrate 101 and the shape of the orthographic projection of the third opening region 104a on the first base substrate 101 are hexagons.

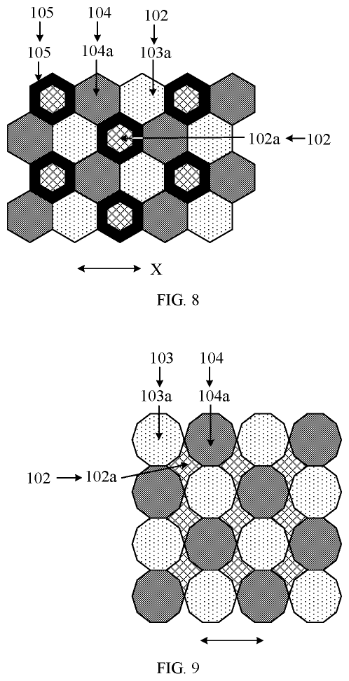

Further, referring to FIG. 7, in the case that the shapes of the first opening region 102a, the second opening region 103a and the third opening region 104a are hexagons, a second spacing region BB is disposed between the first opening region 102a and the opening regions adjacent to the first opening region 102a because of the less area of the first opening region 102a. Referring to FIG. 8, the display substrate 10 further includes a black matrix 105, which is disposed within the second spacing region BB. The black matrix 105 is disposed within the second spacing region BB, thus avoiding light from being emitted from the second spacing region BB and ensuring the display effect of the display substrate.

Alternatively, referring to FIG. 9, the shape of the orthographic projection of the second opening region 103a on the first base substrate 101 and the shape of the orthographic projection of the third opening region 104a on the first base substrate 101 are decagons. And in FIG. 9, the shape of the orthographic projection of the first opening region 102a on the first base substrate 101 is a four-pointed star.

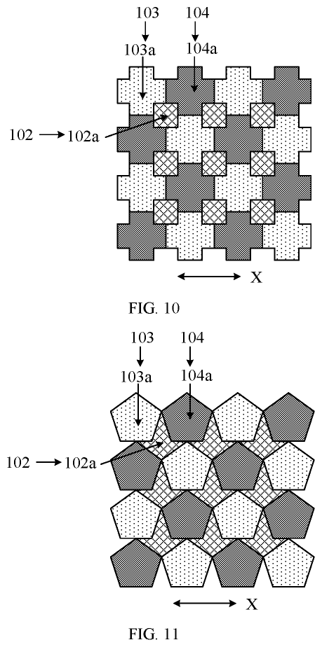

Alternatively, referring to FIG. 10, the shape of the orthographic projection of the second opening region 103a on the first base substrate 101 and the shape of the orthographic projection of the third opening region 104a on the first base substrate 101 are crosses. And in FIG. 10, the shape of the orthographic projection of the first opening region 102a on the first base substrate 101 is a quadrilateral.

Alternatively, referring to FIG. 11, the shape of the orthographic projection of the second opening region 103a on the first base substrate 101 and the shape of the orthographic projection of the third opening region 104a on the first base substrate 101 are both pentagons. And in FIG. 11, the shape of the orthographic projection of the first opening region 102a on the first base substrate 101 is an irregular shape.

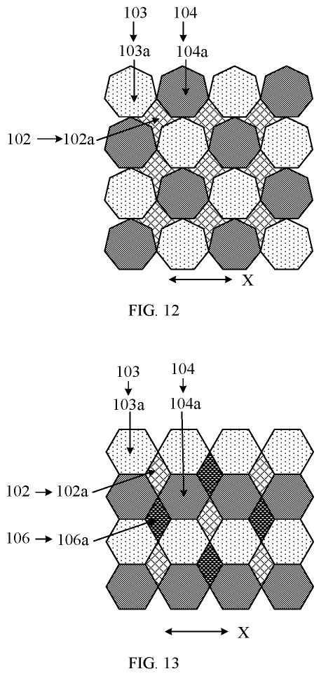

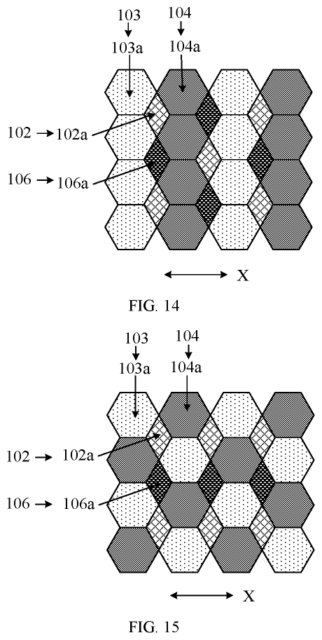

Alternatively, referring to FIG. 12, the shape of the orthographic projection of the second opening region 103a on the first base substrate 101 and the shape of the orthographic projection of the third opening region 104a on the first base substrate 101 are both heptagons. And in FIG. 14, the shape of the orthographic projection of the first opening region 102a on the first base substrate 101 is an irregular shape.

In the embodiments of the present disclosure, referring to FIG. 13, the display substrate 10 further includes a plurality of fourth subpixels 106 disposed on the first base substrate 101. The fourth subpixels 106 emit light of a fourth color. An area of an orthographic projection of a fourth opening region 106a of the fourth subpixel 106 is less than the area of the orthographic projection of the second opening region 103a of the second subpixel 103 on the first base substrate 101 and less than the area of the orthographic projection of the third opening region 104a of the third subpixel 104 on the first base substrate 101.

Optionally, the fourth color is white. That is, the color of the light emitted by the fourth subpixel 106 is white. This can increase the brightness of the display substrate and ensure the display effect of the display substrate. For example, assuming that the transmittance of the fourth subpixel is K, the brightness of the display substrate can be increased by K/4 times.

Referring to FIG. 4 and FIG. 13, a plurality of second subpixels 103 and a plurality of third subpixels 104 are arrayed and the first spacing region AA is disposed between the opening regions of two adjacent subpixels in the target direction X. In the plurality of first spacing regions AA formed by the second opening region 103a of the plurality of second subpixels 103 and the third opening region 104a of the plurality of third subpixels 104, the orthographic projection of the first opening region 102a of the first subpixel 102 on the first base substrate 101 is within the orthographic projection of the first spacing region AA of a first portion on the first base substrate 101, and the orthographic projection of the fourth opening region 106a of the fourth subpixel 106 on the first base substrate 101 is within the orthographic projection of the first spacing region AA of a second portion on the first base substrate 101. The colors of the two adjacent subpixels include at least one of the second color and the third color.

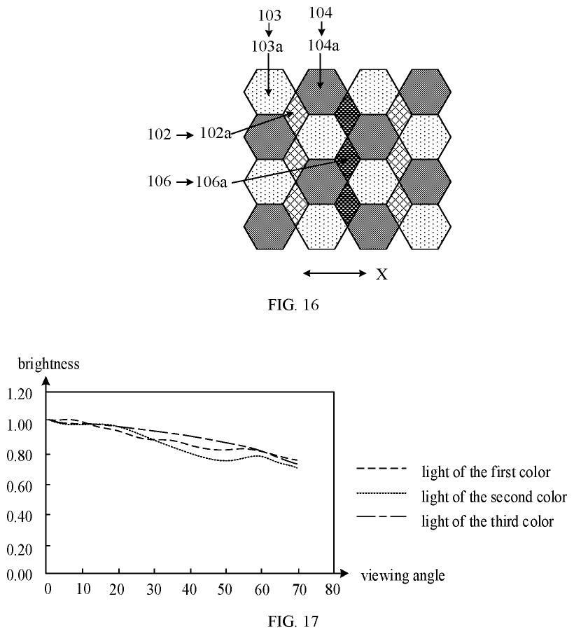

Referring to FIG. 13 and FIG. 14, in the target direction X and in the direction perpendicular to the target direction X, the fourth subpixel 106 is disposed between two adjacent first subpixels 102, and the first subpixel 102 is disposed between two adjacent fourth subpixels 106. Alternatively, referring to FIG. 15, in the direction perpendicular to the target direction X, the fourth subpixel 106 is disposed between two adjacent first subpixels 102, and the first subpixel 102 is disposed between two adjacent fourth subpixels 106. Alternatively, referring to FIG. 16, in the target direction X, the fourth subpixel 106 is disposed between two adjacent first subpixels 102, and the first subpixel 102 is disposed between two adjacent fourth subpixels 106.

FIG. 17 is a schematic diagram of the relationship between the viewing angle and the brightness of the light of each color using the display substrate according to some embodiments of the present disclosure. Referring to FIG. 17, in the case that the viewing angle of the user is larger, the difference between the intensity of the light of a larger wavelength (light of the first color light) and the intensity of the light of a smaller wavelength (light of the second color) is smaller, such that the color viewed by the user does not tend to the color corresponding to the light of a larger wavelength. In other words, in the case that the user's viewing angle is larger, the display panel is less likely to have color cast.

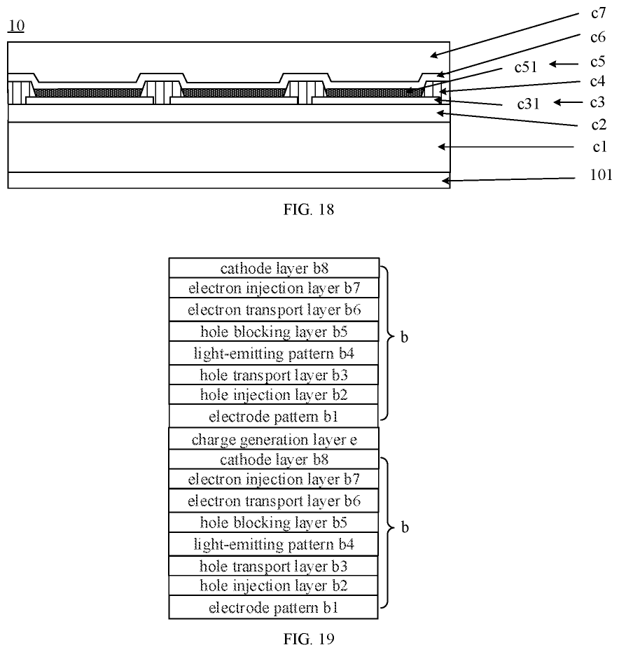

FIG. 18 is a schematic diagram of the structure of still another display substrate according to some embodiments of the present disclosure. With reference to FIG. 18, the display substrate includes: a transistor device layer c1, a planarization layer (PLN) c2, a first electrode layer c3, a pixel definition layer (PDL) c4, a light emitting layer c5, a second electrode layer c6, and a thin-film encapsulation (TFE) c7.

The pixel circuits of the plurality of first sub-pixels 102, the pixel circuits of the plurality of second sub-pixels 103 and the pixel circuits of the plurality of third sub-pixels 104 are disposed in the transistor device layer c1. The first electrode layer c3 includes a plurality of electrode patterns c31, and the light emitting layer c5 includes a plurality of light emitting patterns c51 corresponding to the plurality of electrode patterns c31. Optionally, the first electrode layer c3 is an anode layer, and the second electrode layer c6 is a cathode layer.

In the embodiments of the present disclosure, the thin-film encapsulation c7 is configured to to encapsulate the thin-film between the first base substrate 101 and the thin-film encapsulation c7 to avoid entry of water vapor or oxygen.

In FIG. 18, each electrode pattern c31, the luminescent pattern c51 corresponding to the electrode pattern c31 and the second electrode layer c6 constitute one luminescent unit of a subpixel. FIG. 19 is a schematic diagram of the structure of a subpixel according to some embodiments of the present disclosure. With reference to FIG. 19, the subpixel includes two stacked light-emitting units b and a charge generation layer (CGL) e disposed between the two light-emitting units b. Because each subpixel includes two stacked light-emitting units b, the brightness of the display panel can be improved.

The subpixel further includes a greater number of stacked light emitting-units b. For example, the subpixel includes three stacked light-emitting units b. The embodiments of the present disclosure do not limit the number of light-emitting units b included in the subpixel.

Optionally, the light-emitting unit b is an organic light-emitting diode (OLED). With reference to FIG. 19, each light-emitting unit b includes an electrode pattern b1, a hole injection layer (HIL) b2, a hole transport layer (HTL) b3, a light-emitting pattern b4, a hole blocking layer (HBL) b5, an electron transport layer (ETL) b6, an electron injection layer (EIL) b7, and a cathode layer b8.

In the embodiments of the present disclosure, the opening rate of the subpixel ranges from 10% to 40%. The opening rate of the subpixel is equal to the area of the electrode pattern b1 of the subpixel divided by the area of the subpixel.

In summary, the embodiments of the present disclosure provide a display substrate. In the display substrate, because the area of the orthographic projection of the first opening region on the first base substrate is less, the area of the orthographic projection of the second opening region on the first base substrate is larger, and the area of the orthographic projection of the third opening region on the first base substrate is larger, the first subpixel of the display substrate emits less light, and the second subpixel and the third subpixel emit more light. In addition, because the wavelength of the first color is larger and the proportion of the light of the first color in the light emitted from the display substrate is smaller, the color cast of the display panel can be avoided and the display panel has a better display effect.

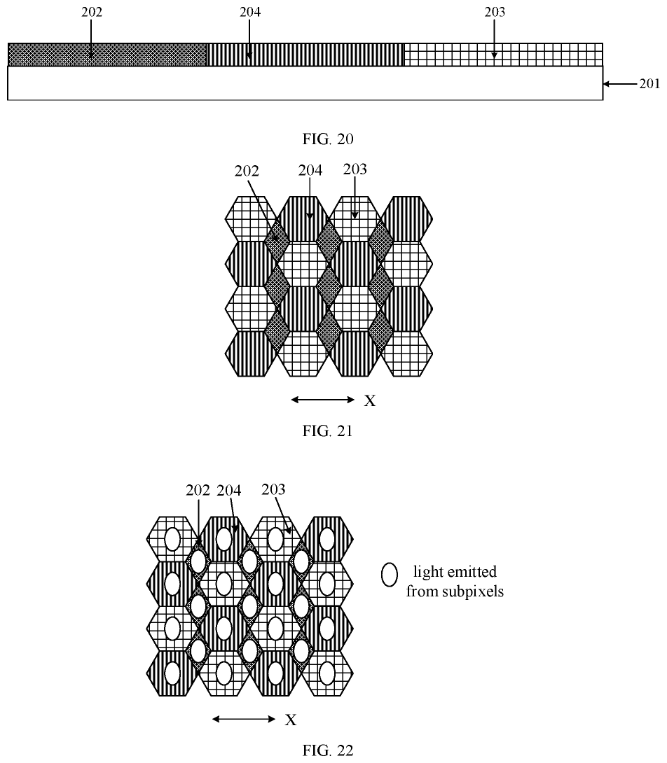

FIG. 20 is a schematic diagram of a structure of a color filter substrate according to some embodiments of the present disclosure. Referring to FIG. 20, the color filter substrate 20 includes a second base substrate 201, a plurality of first color blocks 202 with a first color, a plurality of second color blocks 203 of a second color and a plurality of third color blocks 204 with a third color disposed on the second base substrate 201. A first color block 202, a second color block 203, and a third color block 204 are illustrated in FIG. 20.

Optionally, the wavelength of the light of the first color is greater than the wavelength of the light of the second color and greater than the wavelength of the light of the third color.

FIG. 21 is a top view of the color filter substrate shown in FIG. 20. With reference to FIG. 21, an area of an orthographic projection of the first color block 202 on the second base substrate 201 is less than an area of an orthographic projection of the second color block 203 on the second base substrate 201. In addition, the area of the orthographic projection of the first color block 202 on the second base substrate 201 is less than an area of an orthographic projection of the third color block 204 on the second base substrate 201. That is, the area of the orthographic projection of the first color block 202 on the second base substrate 201 is less, while the area of the orthographic projection of the second color block 203 on the second base substrate 201 and the area of the orthographic projection of the third color block 204 on the second base substrate 201 is larger.

In the target direction X, at least one second color block 203 and/or at least one third color block 204 is disposed between two adjacent first color blocks 202. That is, at least one color block is disposed between two adjacent first color blocks 202 in the target direction X, and the at least one color block includes at least one of the second color block 203 and the third color block 204. Optionally, the target direction X is the row direction of pixels.

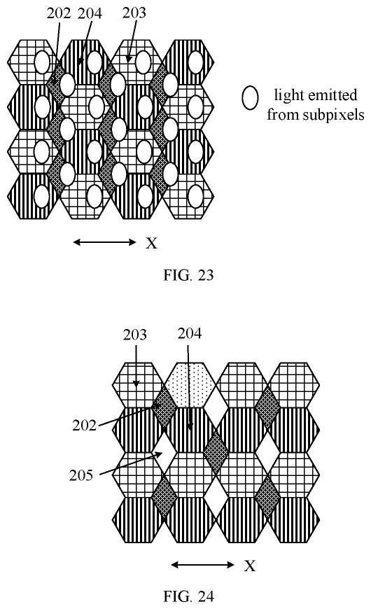

Referring to FIG. 22, the area of the orthographic projection of the first color block 202 on the second base substrate 201 is less, and the light entering the user's eye can be emitted normally from the first color block 202 in the case that the user's viewing angle is small. However, referring to FIG. 23, because the area of the orthographic projection of the first color block 202 on the second base substrate 201 is less, the light that is supposed to enter the user's eye from the first color block 202 enters from the second color block 203 or the third color block 204 adjacent thereto in the case that the user's viewing angle is larger. The user's viewing angle is the angle between the user's sight line and the plane perpendicular to the bearing surface of the second base substrate.

In addition, referring to FIG. 22 and FIG. 23, the light that is supposed to enter the user's eye from the second color block 203 still enters from the second color block 203, and the light that is supposed to enter the user's eye from the third color block 204 still enters from the third color block 204, regardless of whether the user's viewing angle is smaller or larger. That is, because the area of the orthographic projection of the second color block 203 on the second base substrate 201 and the area of the orthographic projection of the third color block 204 on the second base substrate 201 are both larger, the light emitted from the second color block 203 or the third color block 204 is not affected.

In summary, the embodiments of the present disclosure provides a color filter substrate. In the color filter substrate, because the area of the orthographic projection of the first color block is less, the area of the orthographic projection of the second color block of and the area of the orthographic projection of the third color block is larger, the light emitted from the first color block is less light, and the light emitted form the second color block and the third color block is more. Therefore, the proportion of the light of the first color emitted from the display panel is less, avoiding color cast in the display panel, and the display panel has a better display effect.

Optionally, referring to FIG. 24, the color filter substrate 20 further includes a plurality of fourth color blocks 205 disposed on the second base substrate 202. An area of an orthographic projection of the fourth color block 205 on the second base substrate 201 is less than the area of the orthographic projection of the second color block 203 on the second base substrate 201 and less than the area of the orthographic projection of the third color block 204 on the second base substrate 201. Optionally, the fourth color is white.

In the embodiments of the present disclosure, the first color block 202 in the color filter substrate 20 is corresponding to the first subpixel 102 in the display substrate 10, the second color block 203 in the color filter substrate 20 is corresponding to the second subpixel 103 in the display substrate 10, the third color block 204 in the color filter substrate 20 is corresponding to the third subpixel 104 in the display substrate 10, and the fourth color block 205 in the color filter substrate 20 is corresponding to the fourth subpixel 106 in the display substrate 10.

The shape and size of each color block in the color filter substrate 20 are identical to the shape and size of the opening region of the corresponding subpixel in the display substrate 10, respectively. That is, the shape and size of the first color block 202 in the color filter substrate 20 are identical to the shape and size of the first opening 102a of the first subpixel 102 in the display substrate 10, respectively. The shape and size of the second color block 203 in the color filter substrate 20 are identical to the shape and size of the second opening 103a of the second subpixel 103 in the display substrate 10, respectively. The shape and size of the third color block 204 in the color filter substrate 20 are identical the shape and size of the third opening 104a of the third subpixel 104 in the display substrate 10, respectively. The shape and size of the fourth color block 205 in the color filter substrate 20 are identical to the shape and size of the fourth opening region 106a of the fourth subpixel 106 in the display substrate 10, respectively.

In addition, the arrangement of color blocks in the color filter substrate 20 matches the arrangement of subpixels in the display substrate 10. Thus, the arrangement of the color blocks in the color filter substrate 20 can be referred to the arrangement of the subpixels in FIG. 2, FIG. 5, FIG. 6, and FIG. 8 to FIG. 16 above. The first subpixel, the second subpixel, the third subpixel and the fourth sub-pixel in FIG. 2, FIG. 5, FIG. 6, and FIG. 8 to FIG. 16 can be replaced by the first color block, the second color block, the third color block and the fourth color block respectively, thereby acquiring a plurality of color filter substrates. In addition, the arrangement of the color blocks in the color filter substrate can be referred to the above description for the arrangement of the subpixels in the display substrate, which is not repeated in the embodiments of the present disclosure.

In summary, the embodiments of the present disclosure provide a color filter substrate. In the color filter substrate, because the area of the orthographic projection of the first color block is less, the area of the orthographic projection of the second color block of and the area of the orthographic projection of the third color block is larger, the light emitted from the first color block is less light, and the light emitted form the second color block and the third color block is more. Therefore, the proportion of the light of the first color emitted from the display panel is less, avoiding color cast in the display panel, and the display panel has a better display effect.

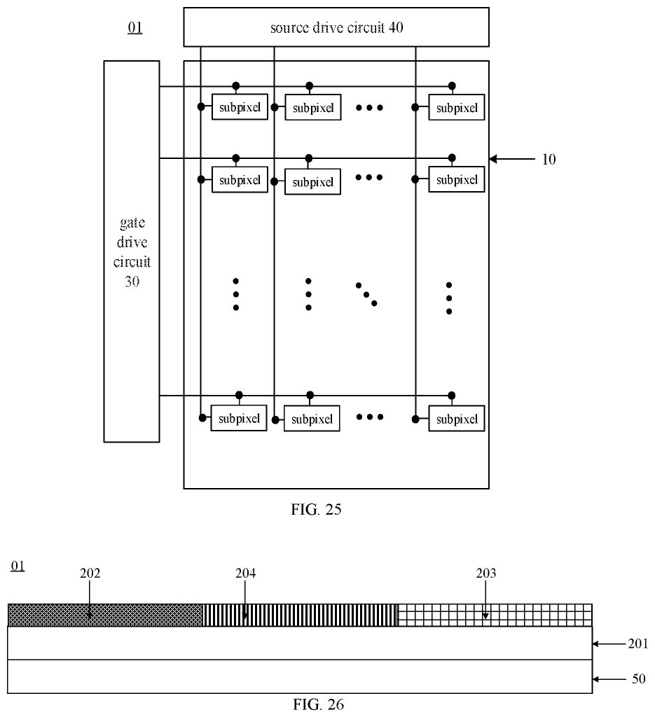

As optional embodiments, FIG. 25 is a schematic diagram of a structure of a display panel according to some embodiments of the present disclosure. Referring to FIG. 25, the display panel 01 includes the display substrate 10 provided in the above embodiments. Referring to FIG. 25, the display panel 01 further includes a gate drive circuit 30 and a source drive circuit 40. The gate drive circuit 30 is connected to each row of subpixels in the display substrate via gate lines for providing gate drive signals to each row of subpixels. The source driver circuit 40 is connected to each column of subpixels in the display substrate 10 via data lines for providing data signals to each column of subpixels.

As other optional embodiments, FIG. 26 is a schematic diagram of a structure of a display panel according to some embodiments of the present disclosure. With reference to FIG. 26, the display panel 01 includes an array substrate 50 and a color filter substrate 20 as provided in the above embodiments.

In the embodiments, the display panel 01 further includes a gate drive circuit 30 and a source drive circuit 40, which is not repeated in the embodiments of the present disclosure.

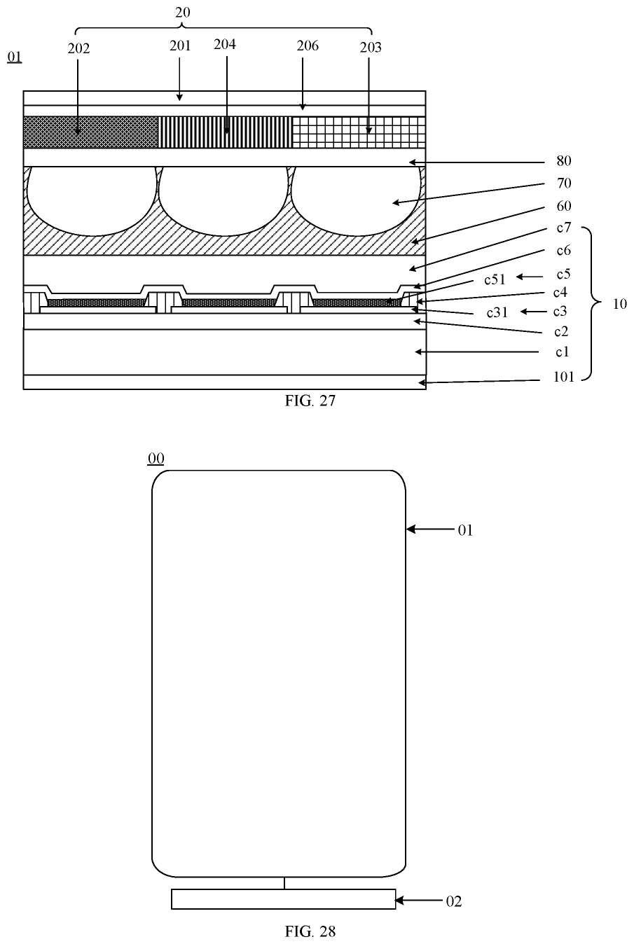

As still other optional embodiments. FIG. 27 is a schematic diagram of a structure of a display panel according to some embodiments of the present disclosure. With reference to FIG. 27, the display panel 01 includes the display substrate 10 provided in the above embodiments and the color filter substrate 20 provided in the above embodiments.

As can also be seen with reference to FIG. 27, the color filter substrate 20 further includes a buffer 206 disposed on the second base substrate 201. The first color block 202, the second color block 203 and the third color block 204 are disposed on a side, distal from the second base substrate 201, of the buffer 206.

In addition, referring to FIG. 27, the display panel 01 further includes adhesive film 60, microlens 70, and polarizing layer 80. The adhesive layer 60 can be configured to hold the display substrate 10 and color filter substrate 20. The microlens 70 can be configured to transmit the light emitted by the subpixels. The polarizing layer 80 can be configured to adjust the light emitted by the subpixels to polarized light.

In the embodiments, the display panel 01 further includes a gate drive circuit 30 and a source drive circuit 40, which is not repeated in the embodiments of the present disclosure.

In summary, the embodiments of the present disclosure provide a display panel. The proportion of the first color light in the light emitted from the display panel is less, thereby avoiding color cast in the display panel, and the display panel has a better display effect,

FIG. 28 is a schematic diagram of a structure of a display device according to some embodiments of the present disclosure. With reference to FIG. 28, the display device 00 includes a power supply assembly 02 and a display panel 01 provided in the above embodiments. The power supply assembly 02 is configured to supply power to the display panel 01.

Optionally, the display device can be an OLED display device, a liquid crystal display device, an electronic paper, a cell phone, a tablet PC, a TV, a monitor, a laptop, a digital photo frame or a navigator, or any other product or component having a display function.

The above descriptions are merely optional embodiments of the present disclosure, but are not intended to limit the present disclosure. Any modification, equivalent replacement, or improvement made without departing from the spirit and principle of the present disclosure shall fall within the protection scope of the present disclosure.

1. A display substrate, comprising:
a first base substrate; and
a plurality of first subpixels, a plurality of second subpixels, and a plurality of third subpixels disposed on the first base substrate, wherein a wavelength of light of a first color emitted by the first subpixels is greater than a wavelength of light of a second color emitted by the second subpixels and greater than a wavelength of light of a third color emitted by the third subpixels, the plurality of first subpixels are provided with a plurality of first opening regions, the plurality of second subpixels are provided with a plurality of second opening regions, and the plurality of third subpixels are provided with a plurality of third opening regions;
wherein an area of an orthographic projection of the first opening region of the first subpixel on the first base substrate is less than an area of an orthographic projection of the second opening region of the second subpixel on the first base substrate and less than an area of an orthographic projection of the third opening region of the third subpixel on the first base substrate.

2. The display substrate according to claim 1, wherein the first color is red, the second color is blue, and the third color is green.

3. The display substrate according to claim 1, wherein
the area of the orthographic projection of the second opening region on the first base substrate is equal to the area of the orthographic projection of the third opening region on the first base substrate; and
a shape of the orthographic projection of the second opening region on the first base substrate is identical to a shape of the orthographic projection of the third opening region on the first base substrate.

4. The display substrate according to claim 3, wherein the plurality of second subpixels and the plurality of third subpixels are arrayed, a first spacing region is disposed between opening regions of two adjacent subpixels in a target direction, and the orthographic projection of the first opening region on the first base substrate is within an orthographic projection of the first spacing region on the first base substrate;
wherein a color of light emitted by the two adjacent subpixels comprises at least one of the second color and the third color.

5. The display substrate according to claim 4, wherein the shape of the orthographic projection of the second opening region on the first base substrate and the shape of the orthographic projection of the third opening region on the first base substrate are hexagons, and a shape of the orthographic projection of the first opening region on the first base substrate is a rhombus.

6. The display substrate according to claim 5, wherein a side length of the hexagon is greater than or equal to a side length of the rhombus.

7. The display substrate according to claim 3, wherein the area of the orthographic projection of the second opening region on the first base substrate is less than or equal to three times the area of the orthographic projection of the first opening region on the first base substrate.

8. The display substrate according to claim 3, wherein a shape of the orthographic projection of the first opening region on the first base substrate, the shape of the orthographic projection of the second opening region on the first base substrate, and the shape of the orthographic projection of the third opening region on the first base substrate are hexagons.

9. The display substrate according to claim 8, wherein
a second spacing region is disposed between the first opening region and at least one of opening regions adjacent to the first opening region; and
the display substrate further comprises: a black matrix, wherein the black matrix is disposed within the second spacing region.

10. The display substrate according to claim 1, wherein boundary lines of any two adjacent opening regions of the plurality of first opening regions, the plurality of second opening regions, and the plurality of third opening regions are overlapped with each other.

11. The display substrate according to claim 1, further comprising: a plurality of fourth subpixels provided with a plurality of fourth opening regions disposed on the first base substrate, wherein the fourth subpixels emit light of a fourth color;
wherein an area of an orthographic projection of the fourth opening region of the fourth subpixel is less than the area of the orthographic projection of the second opening region on the first base substrate and less than the area of the orthographic projection of the third opening region on the first base substrate.

12. The display substrate according to claim 11, wherein the fourth color is white.

13. The display substrate according to claim 1, wherein each of the subpixels of the display substrate comprises two stacked light-emitting units.

14. A color filter substrate, comprising:
a second base substrate; and
a plurality of first color blocks of a first color, a plurality of second color blocks of a second color, and a plurality of third color blocks of a third color disposed on the second base substrate, wherein a wavelength of light of the first color is greater than a wavelength of light of the second color and greater than a wavelength of light of the third color; wherein
an area of an orthographic projection of the first color block on the second base substrate is less than an area of an orthographic projection of the second color block on the second base substrate and less than an area of an orthographic projection of the third color block on the second base substrate; and
at least one of the second color blocks and/or at least one of the third color blocks is disposed between two adjacent first color blocks in a target direction.

15. A display panel, comprising: a display substrate, wherein the display substrate comprises:
a first base substrate; and
a plurality of first subpixels, a plurality of second subpixels, and a plurality of third subpixels disposed on the first base substrate, wherein a wavelength of light of a first color emitted by the first subpixels is greater than a wavelength of light of a second color emitted by the second subpixels and greater than a wavelength of light of a third color emitted by the third subpixels, the plurality of first subpixels are provided with a plurality of first opening regions, the plurality of second subpixels are provided with a plurality of second opening regions, and the plurality of third subpixels are provided with a plurality of third opening regions;
wherein an area of an orthographic projection of a first opening region of the first subpixel on the first base substrate is less than an area of an orthographic projection of a second opening region of the second subpixel on the first base substrate and less than an area of an orthographic projection of a third opening region of the third subpixel on the first base substrate.

16. A display device, comprising: a power supply assembly and the display panel as defined in claim 15;
wherein the power supply assembly is configured to supply power to the display panel.

17. The display panel according to claim 15, wherein the first color is red, the second color is blue, and the third color is green.

18. The display panel according to claim 15, wherein the area of the orthographic projection of the second opening region on the first base substrate is equal to the area of the orthographic projection of the third opening region on the first base substrate; and
a shape of the orthographic projection of the second opening region on the first base substrate is identical to a shape of the orthographic projection of the third opening region on the first base substrate.

19. The display panel according to claim 18, wherein the plurality of second subpixels and the plurality of third subpixels are arrayed, a first spacing region is disposed between opening regions of two adjacent subpixels in a target direction, and the orthographic projection of the first opening region on the first base substrate is within an orthographic projection of the first spacing region on the first base substrate;
wherein a color of light emitted by the two adjacent subpixels comprises at least one of the second color and the third color.

20. A display panel, comprising: an array substrate and the color filter substrate as defined in claim 14.
